(19) United States
(12) Patent Application Publication
(10) Pub. No.: US 2008/0178931 A1
(43) Pub. Date: Jul. 31, 2008

(54) Multi-junction solar cell

(76) Inventors: Hye-Won Seo, Little Rock, AR (US); Li-Wei Tu, Kaohsiung (TW); Cheng-Ying Ho, Sen -Gon Town (TW); Chang-Kong Wang, Jhong-Li (TW); Yuan-Ting Lin, Kaohsiung City (TW)

Correspondence Address: WRIGHT, LINDSEY & JENNINGS LLP, 200 WEST CAPITOL AVENUE, SUITE 2300, LITTLE ROCK, AR, 72201-3699, US

(21) Appl. No.: 12/011,101

(22) Filed: Jan. 24, 2008

Related U.S. Application Data
(60) Provisional application No. 60/897,542, filed on Jan. 26, 2007.

(51) Int. Cl. H01L 31/04

(52) U.S. Cl. 136/255

(57) ABSTRACT

A photovoltaic device having multi-junction nanostructures deposited as a multi-layered thin film on a substrate. Preferably, the device is grown as InₓGa₁₋ₓN multi-layered junctions with the gradient x, where x is any value in the range from zero to one. The nanostructures are preferably 5-500 nanometers and more preferably 10-20 nanometers in diameter. The values of x are selected so that the bandgap of each layer is varied from 0.7 eV to 3.4 eV to match as nearly as possible the solar energy spectrum of 0.4 eV-4 eV.

### CROSS-REFERENCE TO RELATED APPLICATIONS

This application claims the benefit of U.S. Provisional Application No. 60/897,542 filed Jan. 26, 2007, the disclosure of which is incorporated herein by reference.

### STATEMENT REGARDING FEDERALLY SPONSORED RESEARCH OR DEVELOPMENT

Not Applicable.

### BACKGROUND OF THE INVENTION

1. Field of the Invention

The present invention relates to high-efficiency, solar cells, and in particular, to high-efficiency solar cells utilizing multi-junction nanostructures.

2. Brief Description of the Related Art

The urgent need for the development of new generation technology for solar cells is widely agreed upon. In the last five years, the production of energy by solar cells has increased steadily by an average of 30% per year based on the expected near-future crisis of finite resources of oil and other fuels. For instance, a Palo Alto company announced in June 2006 the building of the world's largest solar cell factory at a cost of around $100 million. In 2006, Honda Motors established an innovative solar cell company, Honda Soltec Co., and has started preparing the next generation of energy sources.

Currently, crystalline silicon is the most common bulk material for solar cells. Various thin-film and multi-layer thin-film technologies have been developed to reduce the cost of manufacturing solar cells from that of bulk materials. Materials other than silicon, such as CdTe, CIGS (Copper Indium Gallium Selenide), CIS (Copper Indium Selenide), GaAs, GaInP-GaAs-Ge, light-absorbed dyes, quantum dots and organics/polymers have been found to be possible solar cell materials. All materials used for solar cells share an efficiency issue. For instance, silicon solar cell efficiencies range from 6% for amorphous silicon-based solar cells to 30% or higher for multi-junction cells. Such inefficiencies waste most of the solar energy. One reason for the low efficiency is that photons with energy less than that of the material's bandgap frequency are not absorbed. On the contrary, the excess energy will be wasted for photons with energy higher than the bandgap. Furthermore, solar energy is spread over a spectrum from 0.4 eV to 4.0 eV. Single junction solar cells cannot capture the energy from the entire spectrum. Accordingly, multi-junction cells have been developed to capture more of the available energy spectrum.

Conventional GaInP-GaAs-Ge junction cells (1.85 eV, 1.42 eV, & 0.67 eV) have shown the best performance in multi-layered solar cells. But these devices are nevertheless limited because of their high cost and because their efficiency is still not high enough for producing economical electricity.

The limitations of the prior art are overcome by the present invention as described below.

### BRIEF SUMMARY OF THE INVENTION

The present invention is a high-efficiency solar cell utilizing multi-layered nanostructures, such as nanorods. The solar cell comprises a substrate upon which a population of multi-junction nanostructures is grown.

In solar cell devices, energy conversion efficiency is the key to performance. In the present invention, efficiency is improved through properly selecting materials, scaling the device size, and increasing the layered junction number, which can be easily tuned by growth conditions. Since this solar cell device can be fabricated in line with standard semiconductor processes, development and manufacturing costs can be kept low.

The efficiency of solar cells produced according to the present invention is enhanced by (1) enhancing absorption of photons and (2) utilizing more of the energy of the entire solar spectrum. As to (2), J. Wu et al. [Ref. 1] report that InₓGa₁₋ₓN ternary alloys can extend their bandgaps over a very wide energy range (0.7 eV to 3.4 eV) and thus provide a near-perfect match to the solar energy spectrum, 0.4 eV-4 eV.

As to (1), it has been believed that one solar photon never frees more than one electron from an atom to contribute electrical current even if it carries enough energy to unleash several electrons. Schaller and Victor I. Klimov at Los Alamos [Ref. 4] have recently reported that photons in semiconductors of a few nanometers in diameter unleash multiple electrons.

The present invention takes advantage of these two observations in a solar cell having multi-junction nanostructures. Multiple junctions are able to extract more of the energy in the entire solar spectrum. By appropriate sizing of the nanostructures, multiple electrons may be excited by a single photon. The combination should produce solar cells with greatly enhanced efficiencies.

A preferred material for forming such nanostructures is InₓGa₁₋ₓN. Utilizing the techniques described in {Refs. 5, 6], defect free InₓGa₁₋ₓN multi-layered nanorods may be fabricated by alloying GaN with In in a multilayer configuration.

The efficiency of solar cells manufactured according to the present invention may be increased by increasing the number of layered junctions. This can be accomplished during the manufacturing process simply by changing the ratio between Ga and In during the growth of the nanostructures. Only three sources (In, Ga, & N) are necessary during the fabrication, which simplifies the manufacturing process and reduces the production cost for high-efficiency solar cells.

One embodiment of the present invention is therefore a solar cell of improved photoelectric conversion efficiency having multi-layered nanostructures deposited as a multi-layered thin film on a substrate.

A second embodiment of the present invention is a highly efficient solar cell having InₓGa₁₋ₓN multi-layered junctions with the gradient x, where x is any value in the range from zero to one.

A third embodiment of the present invention is a highly efficient solar cell having InₓGa₁₋ₓN multi-layered junctions in a population of nanorods a few nanometers in diameter so that a single photon may excite multiple electrons.

A fourth embodiment of the present invention is a high-efficiency solar cell of InₓGa₁₋ₓN multi-layered nanorods with a gradient chemical stoichiometry such that the bandgap energy of each layer is varied from 0.7 eV to 3.4 eV to match as nearly as possible the solar energy spectrum of 0.4 eV-4 eV.

A fifth embodiment of the present invention is a method of fabricating InₓGa₁₋ₓN nanorods that are free from structural defects using capillary condensation in lieu of the commonly used extrinsic metallic catalyst as the catalyst for nanorod growth.

A sixth embodiment of the present invention is a high efficiency multi-layered solar cell having both a modulated gradient bandgap in InₓGa₁₋ₓN multi-layers and optimized nanostructure quantum confinement effect.

Embodiments consistent with the present disclosure may be manufactured using various thin film growth methods, including molecular beam epitaxy, chemical vapor deposition, physical vapor deposition, laser ablation, hydride vapor phase epitaxy, and sputtering.

These and other features, objects and advantages of the present invention will become better understood from a consideration of the following detailed description of the preferred embodiments and appended claim in conjunction with the drawings as described following.

### BRIEF DESCRIPTION OF THE SEVERAL VIEWS OF THE DRAWINGS

FIGS. 1-6 illustrate one method for growing nanorods by capillary condensation consistent with the present invention. FIG. 1 is a schematic diagram of the first stage of film growth showing the growth of islands and the condensation of Ga droplets.

FIG. 2 is a schematic diagram of side-by-side islands acting as capillary tubes to attract Ga droplets, which serve as the foundation for the formation of nanorods.

FIG. 3 is a schematic diagram showing the second stage of film growth where the nanorods begin to protrude.

FIG. 4 is a schematic diagram showing how the GaN nanorods grow faster along the <0001>direction via the Vapour-Liquid-Solid (VLS) mechanism by the reaction of nitrogen plasma with Ga liquid clusters while the surrounding GaN islands also grow alongside, although at a slower rate. [Ref. 5]

FIG. 5 is a schematic diagram of the third stage of film growth showing multi-layered nanorod growth with a gradient in Indium concentration, GaN/InᵤGa₁₋ᵤN/InᵥGa₁₋ᵥN/In_{w}Ga_{1-w}N/InₓGa₁₋ₓN/In_{y}Ga_{1-y}N/In_{z}Ga_{1-z}N/ . . . /InN), where (0<u<v<w<x<y<z<1) or vice versa.

FIG. 6 is a schematic diagram of the deposition of an insulating layer and metallic contacts.

FIGS. 7-8 illustrate one method of growing nanocolumns consistent with the present invention. FIG. 7 is a schematic diagram of nanocolumns grown on a substrate in nitrogen rich conditions. The method of capillary condensation is not used in this method.

FIG. 8 is a schematic diagram of the growth of multi-layered nanocolumns with a gradient in Indium concentration, GaN/InᵤGa₁₋ᵤN/InᵥGa₁₋ᵥN/In_{w}Ga_{1-w}/InₓGa₁₋ₓN/In_{y}Ga_{1-y}N/In_{z}Ga_{1-z}N/ . . . /InN), where (0<u<v<w<x<y<z<1) or vice versa.

FIGS. 9-10 illustrate another method of growing nanocolumns consistent with the present invention. FIG. 9 is a schematic diagram of nanocolumns grown on a substrate in nitrogen rich conditions. The method of capillary condensation is not used in this method.

FIG. 10 is a schematic diagram of the growth of multi-layered p-i-n nanocolumns, n-type GaN/InᵤGa₁₋ᵤN/GaN/InᵥGa₁₋ᵥN/GaN/In_{w}Ga_{1-w}N/GaN/Inₓ/Ga₁₋ₓN /GaN/In_{y}Ga_{1-y}N/GaN/In_{z}Ga_{1-z}N/. . . /p type GaN, where (0,<u<v<w<x<y<z<1) or vice versa.

### DETAILED DESCRIPTION OF THE INVENTION

The present invention is a high-efficiency solar cell utilizing multi-layered nanostructures, such as nanorods and nanocolumns. The solar cell comprises a substrate upon which a population of multi-junction nanostructures is grown, an insulating layer and metallic contacts.

As used in this specification, including the claims, “aspect ratio” means the length of an axis of a nanostructure divided by the average of the lengths of the two remaining axes, where the two remaining axes are the two axes most nearly equal to each other. “Nanostructure” means a structure having at least one axis with a characteristic dimension small enough to exhibit quantum confinement effects. A “one dimensional nanostructure” means a nanostructure having two axes with a characteristic dimension small enough to exhibit quantum confinement effects. Such characteristic dimensions are less than about 500 nm, less than 100 nm, less than 50 nm, less than 20 nm, or less than 10 nm. The axes of the nanostructure may be straight, or they may be bent or curved. Any cross-sectional geometry of the nanostructure is considered to be included within the scope of the present invention. A “diameter” of a one dimensional nanostructure means the average of the dimensions of the two axes with a characteristic dimension small enough to exhibit quantum confinement effects.

Multiple junctions are able to extract more of the energy in the entire solar spectrum. The efficiency of solar cells manufactured according to the present invention can be increased by increasing the number of layered junctions. Multiple junctions are formed during the manufacturing process by changing the ratio between Ga and In during the growth of the nanostructures. The bandgap of each layer is varied from 0.7 eV to 3.4 eV to match as nearly as possible the solar energy spectrum of 0.4 eV-4 eV.

By appropriate sizing of the nanostructures, multiple electrons may be excited by a single photon due to the quantum confinement size effect. The size effect is achieved for nanostructures with a diameter of a few nanometers or sub-micrometers, preferably 5-500 nanometers and more preferably 10-20 nanometers. The aspect ratio of the nanostructures of the present invention is greater than 3.0, more preferably greater than 5.0 and most preferably greater than 10.0.

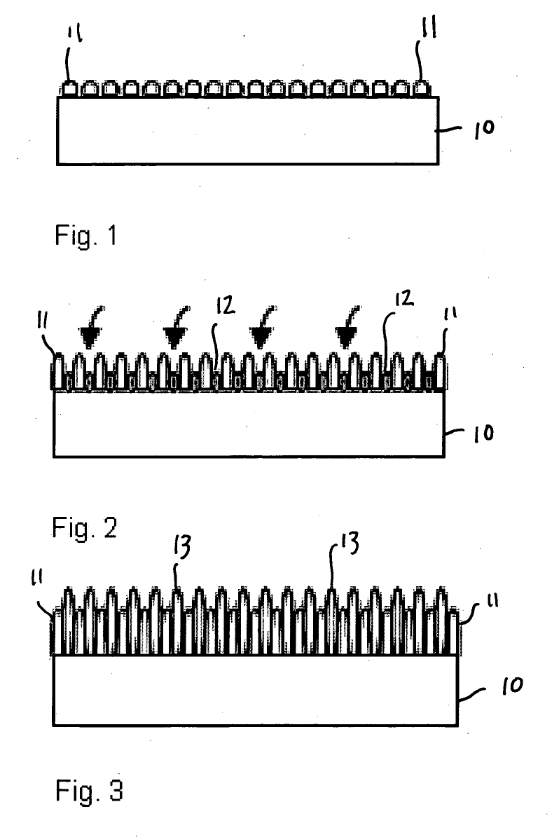

A preferred method of growing straightly aligned multi-layered InₓGa₁₋ₓN (where x represents any value from zero to one) crystal nanorods for solar cell applications is capillary condensation as illustrated in FIGS. 1-6.

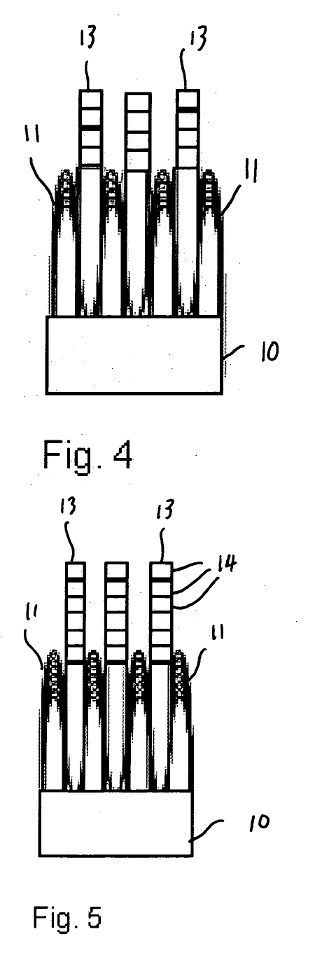

As shown in FIGS. 1 and 2, in the first stage of film growth on a substrate 10, islands 11 of GaN appear and Ga droplets 12 begin to condense. The side-by-side islands of GaN act as capillary tubes to attract Ga droplets, which serve as the foundation for the formation of nanorods. FIGS. 3 and 4 show the second stage of film growth where the nanorods 13 begin to protrude, since the GaN nanorods 13 grow faster along the <0001>direction via the Vapour-Liquid-Solid (VLS) mechanism by the reaction of nitrogen plasma with Ga liquid clusters. The surrounding GaN islands 11 also grow alongside, although at a slower rate. By altering the temperature and Ga/N ratio during thin film growth, the length-to-diameter aspect ratio and density of the nanorods 13 can be controlled as described in [Ref. 5]. While the diameter is important to the size effect discussed above, the preferred length of the nanorods 13 will be determined by economic considerations of efficiency versus cost of manufacturing. Longer nanorods 13 require longer growing times and therefore are more costly than shorter nanorods 13.

FIG. 5 shows the third stage of film growth with nanorods 13 having multiple layers 14 being formed as, GaN/InᵤGa₁₋ᵤN/InᵥGa₁₋ᵥN/In_{w}Ga_{1-w}N/InₓGa₁₋ₓ/In_{y}Ga_{1-y}N/In_{z}Ga_{1-z}N/ . . . /InN), where (0<u<v<w<x<y<z<1) or vice versa. Although InGaN is the preferred material to form the solar cell of the present invention, other embodiments of the present invention may be grown as thin films of Al₁₋ₓInₓN, Ga₁₋ₓAlₓN or other semiconductors from Groups. II-VI and III-V. GaN, however, has a particular advantage in applications where resistance to radiation damage is important, such as space satellite applications.

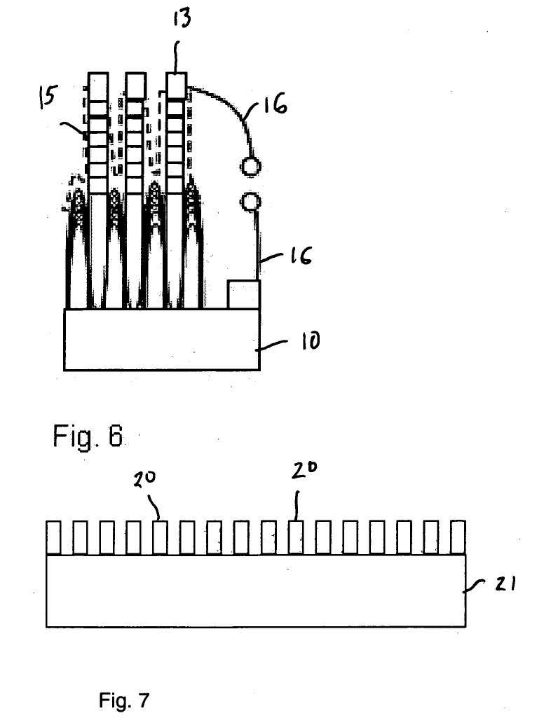

In the final step as shown in FIG. 6, an insulating layer 15 and metallic contacts 16 are deposited to create the finished solar cell.

The capillary condensation effect is a proven mechanism for growing straightly aligned GaN nanostructures without a hetero-catalyst. In fabricating GaN nanorods, In doping with various concentrations into GaN nanorods may be applied. To form p-n junctions, Mg can be used for hole doping while Si or Al may be proper for electron doping. Tunnel junctions or metallic barriers may be used to pass current from one layer to the next. An anti-reflection coating can be used to reduce the light loss on the surface of multi-layered nanorods.

The proper thickness of each layer of a multi-layered solar cell may be determined by generating a uniform photocurrent throughout all the nanorod thicknesses. The waste of solar energy is reduced when the number of junctions is increased. In contrast to conventional solar cells made with hetero-materials, multi-layer fabrication using the methods described above may be performed by changing the ratio between Ga and In during the growth of the nanostructures.

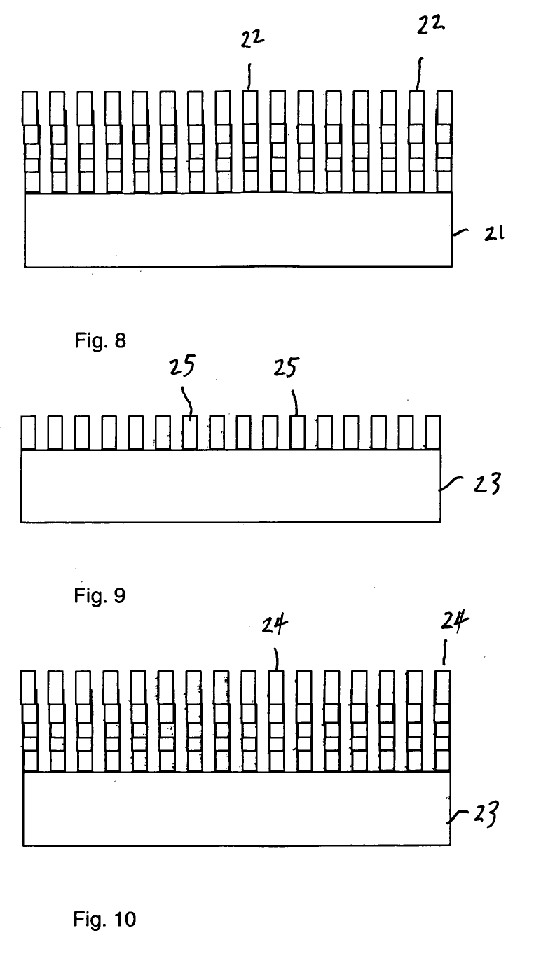

Although the preferred embodiments of the present invention have been described primarily with reference to nanorods, other nanostructures, such as nanotubes, nanowires and nanocolumns, are considered to be within the scope of the present invention as set forth in the appended claims. Nanocolumns may be grown in nitrogen conditions without the use of capillary condensation. For example, FIG. 7 is a schematic diagram of nanocolumns 20 grown on a substrate 21 in nitrogen rich conditions. FIG. 8 shows multi-layered nanocolumns 22, GaN/InᵤGa₁₋ᵤN/InᵥGa₁₋ᵥN/In_{w}Ga_{1-w}N/InₓGa₁₋ₓN/In_{y}Ga_{1-y}N/In_{z}Ga_{1-z}N/ . . . /InN), where (0<u<v<w<x<y<z<1) or vice versa. An alternative embodiment of the invention is shown in FIGS. 9 and 10 in which nanocolumns 25 are grown on a substrate 23 under nitrogen rich conditions to produce multi-layered p-i-n nanocolumns 24, n-type GaN/InᵤGa₁₋ᵤN/GaN/InᵥGa₁₋ᵥN/GaN/In_{w}Ga_{1-w}N/GaN/InₓGa₁₋ₓN/GaN/In_{y}Ga_{1-y}N/GaN/In_{z}Ga_{1-z}N/ . . . /p type GaN), where (0<u<v<w<x<y<z<1) or vice versa. The method of capillary condensation is not used in this method.

Further, although the preferred embodiments have been primarily described with reference to InGaN nanostructures produced by capillary condensation, the present invention is not limited to this material or this manufacturing process. Other semiconductors from Groups III-V and II-VI including without limitation, Al₁₋ₓInₓN, Ga₁₋ₓAlₓN, Ga₁₋ₓInₓP, Al₁₋ₓInₓP, Gal₁₋ₓAlₓP, Ga₁₋ₓInₓAs, Ga₁₋ₓInₓAs, InO, InS, InSe, ZnO with proper doping, CIS and CIGS are contemplated as being within the scope of the present invention. Other manufacturing processes usable in the present invention could include without limitation the hetero-catalyst method and thin-film growth methods, including molecular beam epitaxy, chemical vapor deposition, physical vapor deposition, laser ablation, hydride vapor phase epitaxy, low pressure vapor epitaxy and sputtering.

The present invention has been described with reference to certain preferred and alternative embodiments that are intended to be exemplary only and not limiting to the full scope of the present invention.

### REFERENCES:

1. J. Wu, W. Walukiewicz, K. M. Yu, J. W. Ager III, E. E. Haller, Hai Lu, and William J. Schaff, Appl. Phys. Lett. 80, 4741 (2002).
2. Masahiko Muramoto, and Takashi Hayakawa, U.S. Pat. No. 6,459,034 (2002)
3. A. Marti and G. L. Araujo, Sol. Energy Mater. Sol. Cells 43, 203 (1996)
4. R. D. Schaller, and V. I. Klimov, Phys. Rev. Lett. 92, 186601 (2004)
5. H. W. Seo, Q. Y. Chen, L. W. Tu, C. L. Hsiao, M. N. Iliev, and Wei-Kan Chu. Phys. Rev. B 71, 235314 (2005).
6. H. W. Seo, Q. Y. Chen, M. N. Iliev, L. W. Tu, C. L. Hsiao, J. K. Meen, and Wei-Kan Chu. Appl. Phys. Lett 88, 153124 (2006).

What is claimed is:

1. A photovoltaic device, comprising
a substrate; and
a population of layered multiple junction one-dimensional nanostructures deposited on said substrate.

2. The device of claim 1, wherein said nanostructures comprise nanorods.

3. The device of claim 1, wherein said nanostructures comprise nanotubes.

4. The device of claim 1, wherein said nanostructures comprise nanowires.

5. The device of claim 1, wherein said nanostructures comprise nanocolumns.

6. The device of claim 1, wherein said nanostructures comprise a semiconductor selected from Group II-V and Group II-VI semiconductors.

7. The device of claim 6, wherein said nanostructures comprise layered multiple junction InₓGa₁₋ₓN with the gradient x, wherein said gradient x is selected from any value in the range from zero to one.

8. The device of claim 1, wherein said nanostructures have a diameter of about 5 to about 500 nanometers.

9. The device of claim 8, wherein said nanostructures have a diameter of about 10 to about 20 nanometers.

10. The device of claim 1, wherein the bandgap of each junction varies from 0.7 eV to 3.4 eV to approximately match the solar energy spectrum of 0.4 eV-4 eV.

11. The device of claim 1 wherein said nanostructures are grown by capillary condensation.

12. The device of claim 1 grown by hetero-catalyst method and thin film growth methods, including molecular beam epitaxy, chemical vapor deposition, physical vapor deposition, laser ablation, hydride vapor phase epitaxy, low pressure vapor epitaxy and sputtering.

13. The device of claim 6, wherein said semiconductor is selected from the group consisting of Al₁₋ₓInₓN, Ga₁₋ₓAlₓN, Ga₁₋ₓInₓP, Al₁₋ₓInₓP, Gal₁₋ₓAlₓP, Ga₁₋ₓInₓAs, and Ga₁₋ₓInₓAs, where the gradient x is selected from any value in the range from 0 to 1.

14. The device of claim 6, wherein said semiconductor is selected from the group consisting of doped InO, InS, InSe, ZnO, CIS and CIGS.

15. The device of claim 1, wherein said nanostructures have an aspect ratio greater than 3.0

16. The device of claim 15, wherein said nanostructures have an aspect ratio greater than 5.0

17. The device of claim 16, wherein said nanostructures have an aspect ratio greater than 10.0

18. The device of claim 5, wherein said nanocolumns are grown in nitrogen rich conditions.

19. The device of claim 5, wherein said nanocolumns comprise multi-layered p-i-n nanocolumns.
